(19) United States
(12) Patent Application Publication
(10) Pub. No.: US 2012/0187484 A1
(43) Pub. Date: Jul. 26, 2012

(54) LATERAL DOUBLE DIFFUSED METAL OXIDE SEMICONDUCTOR DEVICE

(76) Inventors: Cheol-Ho CHO, Seoul (KR); Choul-Joo Ko, Seoul (KR)

(21) Appl. No.: 13/216,963

(22) Filed: Aug. 24, 2011

(30) Foreign Application Priority Data
Jan. 24, 2011 (KR) 10-2011-0006948

(51) Int. Cl. H01L 29/78

(52) U.S. Cl. 257/339; 257/E29.256

(57) ABSTRACT

A lateral double diffused metal oxide semiconductor (LDMOS) device includes a first buried layer having a second conduction type formed in an epitaxial layer having a first conduction type, a first high-voltage well having the second conduction type formed above one region of the first buried layer, a first drain diffusion region having the first conduction type formed above another region of the first buried layer, a second drain diffusion region having the second conduction type formed in a partial region of the first drain diffusion region, the second drain diffusion region including a gate pattern and a drain region, and a first body having the first conduction type including a source region and having a surface in contact with the second drain diffusion region.

The present application claims priority under 35 U.S.C. §119 to Korean Patent Application No. 10-2011-0006948 (filed on Jan. 24, 2011), which is hereby incorporated by reference in its entirety.

### BACKGROUND

In general, with the improvement in the integration of semiconductor devices and the development in manufacturing and design techniques, there has been an increasing attempt to construct systems using a single semiconductor chip. The construction of a system using a single chip has been developed focusing on a technique for integrating a controller, a memory, and circuits operating at a low voltage as a single chip.

However, in order to minimize weight and size of the system, it may be necessary to integrate circuits which control the power supply of the system, that is, certain main functional circuits associated with an input terminal and an output terminal, as a single chip. The input terminal and the output terminal are circuits to which a high voltage is applied, and thus may not be constituted by general low-voltage CMOS circuits. For this reason, the input terminal and the output terminal are constituted by high-voltage power transistors.

Accordingly, in order to minimize the size and/or weight of the system, it may be necessary to integrate the input and output terminals of the power supply and a controller as a single chip. To this end, a power IC technique is known in which a high-voltage transistor and a low-voltage CMOS transistor are integrated as a single chip.

The power IC technique contributes the improved structure of a vertical DMOS (VDMOS) device which is a discrete power transistor. With the power IC technique, a LDMOS (lateral DMOS) device is implemented in which the drain is arranged horizontally such that a current flows horizontally, and the drift region is arranged between the channel and the drain, thereby securing high-voltage breakdown.

The LDMOS device of the related art will be described with reference to the accompanying drawings.

FIG. 1 is a cross sectional view illustrating the structure of an LDMOS device of the related art which is used for a high-side device. An LDMOS device for a high-side device may be generally used in a circuit for supplying power.

As illustrated in FIG. 1, a semiconductor substrate (P-SUB) in which an active region is defined by an isolation layer 60, includes an N-buried layer (NBL) 90 and a high-voltage N-well (HV NWELL) 80. In particular, the high-voltage N-well (HV NWELL) 80 is formed on the NBL 90.

A gate pattern 50 is formed on the semiconductor substrate to overlap the isolation layer 60. A P-body 30 is formed in the high-voltage N-well (HV NWELL) 80 at one side of the gate pattern 50, and a source 40 is formed in the P-body 30. A low voltage N-well (LV NWELL) 70 is formed in the high-voltage N-well (HV NWELL) 80 at the other side of the gate pattern 50, and a drain 10 is formed in the low voltage N-well (LV NWELL) 70.

In the LDMOS device, a deep sink region (DEEPN+) 20 isolated from the drain 10 by the isolation layer 60 is provided as a guard ring, thereby preventing an effect of a parasitic PNP. In other words, when forming the deep sink region 20 as a guard ring, if a current flows backward in an inductor, that is, if a hole current is generated, holes are recombined in the NBL 90, and uncombined holes flow in the deep sink region 20 to prevent the hold current from flowing into the substrate, thereby preventing the effect of the parasitic PNP.

As illustrated in FIG. 2, an LDMOS device of the related art for a low-side device may be used while being connected to the ground of the circuit. In an LDMOS device of the related art for a low-side device, the voltage of the drain region may be lower than that of the substrate. At this time, parasitic NPN may operate and a large quantity of electrons may be injected. In order to prevent the injected electrons from being injected into an active circuit, the NBL 200 serving as a guard ring has been provided, which leads to an increase in the chip size.

The LDMOS device illustrated in FIG. 2 has a characteristic that a negative bias may not be applied to the drain region. That is, in the case where a negative bias is applied to the drain region, since the voltage of the drain region is lower than that of the substrate, a P-N junction is turned on and electrons are injected into the substrate, thus preventing complete isolation from the substrate.

Further, in the LDMOS device, the devices which are used for a low-side device and a high-side device are different in structure. For this reason, there is a problem in that the devices for the low-side device and the high-side device need to be manufactured separately.

### SUMMARY

Embodiments relate to a semiconductor device, and in particular, to a lateral double diffused metal oxide semiconductor (LDMOS) device configured for use as both a low-side device and a high-side device and which achieves complete isolation from a semiconductor substrate.

Embodiments relate to an LDMOS device configured for connection to both the low-side device and the high-side device.

Further, embodiments relate to an LDMOS device in which a second conduction type drain diffusion region connected to a drain region and a first conduction type drain diffusion region connected to a second conduction type buried layer are formed, achieving complete isolation from a semiconductor substrate.

Embodiments are not limited to those mentioned above, and other embodiments will be apparently understood by those skilled in the art through the following description.

In accordance with embodiments, there is provided an LDMOS device including at least one of the following: a second conduction type buried layer which is formed in a first conduction type epitaxial layer, wherein the first conduction type is different than the second conduction type; a second conduction type high-voltage well formed on and/or over one region of the second conduction type buried layer; a first conduction type drain diffusion region formed on and/or over another region of the second conduction type buried layer; a second conduction type drain diffusion region formed in a partial region of the first conduction type drain diffusion region, the second conduction type drain diffusion region including a gate pattern and a drain region; and a first conduction type body which has a surface in contact with the second conduction type drain diffusion region, and includes a source region.

Further, the second conduction type high-voltage well may include an N+ region, a second conduction type well, and a second conduction type deep sink region.

The LDMOS device may further include a first conduction type well formed between the second conduction type high-voltage well and the first conduction type drain diffusion region. The first conduction type well may include a P+ region and a dummy region into which first conduction type impurity ions are implanted. The first conduction type well, the first conduction type drain diffusion region, and the second conduction type high-voltage well may be isolated from each other by a device isolation film. Further, the first conduction type drain diffusion region and the second conduction type drain diffusion region may be formed by a drive-in process.

The LDMOS device may further include a first conduction type buried layer formed between the first conduction type drain diffusion region and the second conduction type buried layer. A P-N junction of the second conduction type drain diffusion region and the first conduction type drain diffusion region may be turned on depending on a voltage which is applied to the drain region of the LDMOS device.

In accordance with embodiments, when an LDMOS device is used for a low-side device and a high-side device, since parasitic NPN and PNP are prevented using the first conduction type drain diffusion region and the second conduction type drain diffusion region, it is not necessary to provide an electron guard ring, making it possible to minimize the size of a semiconductor chip.

Further, in accordance with embodiments, by using the first conduction type drain diffusion region and the second conduction type drain diffusion region, electrons or holes which are generated in accordance with a voltage applied to the drain are prevented from flowing into the semiconductor substrate. It is possible, therefore, to provide an LDMOS device which can achieve complete isolation from the semiconductor substrate and can be applied to various circuit devices, e.g., Active Matrix Organic Light-Emitting Diode (AMOLED) to which a negative bias needs to be applied.

### DRAWINGS

The above and other features of the invention will become apparent from the following description of embodiments given in conjunction with the accompanying drawings, in which:

FIG. 1 is a cross sectional view illustrating an LDMOS device of the related art which is used for a high-side device.

FIG. 2 is a cross sectional view illustrating an LDMOS device of the related art which is used for a low-side device.

Example FIG. 3 is a cross sectional view illustrating the structure of an LDMOS device in accordance with embodiments.

Example FIG. 4 is a cross sectional view illustrating an operation procedure when an LDMOS device in accordance with embodiments is used for a high-side device.

Example FIG. 5 is a cross sectional view illustrating an operation procedure when an LDMOS device in accordance with embodiments is used for a low-side device.

Example FIG. 6 is a graph for comparing a current gain of parasitic PNP measured in an LDMOS device in accordance with embodiments and a current gain measured in an LDMOS device of the related art.

Example FIG. 7 is a graph for comparing an alpha value when parasitic NPN of an LDMOS device in accordance with embodiments operates and an alpha value in an LDMOS device of the related art.

Example FIG. 8 is a cross sectional view illustrating an operation procedure when an LDMOS device in accordance with embodiments is applied to an AMOLED.

### DESCRIPTION

Advantages and features of the invention and methods of accomplishing the same may be understood more readily by reference to the following detailed description of embodiments and the accompanying drawings.

Hereinafter, embodiments will be described in detail with reference to the accompanying drawings which form a part hereof.

Example FIG. 3 is a cross sectional view illustrating the structure of an LDMOS device in accordance with embodiments.

As illustrated in example FIG. 3, an LDMOS device in accordance with embodiments may include a first conduction type epitaxial layer (P-EPI) 300, a second conduction type buried layer (NBL) 302, a second conduction type high-voltage well 304, a first conduction type buried layer (PBL) 306, a second conduction type drain diffusion region (LVNA (N-type)) 308, a first conduction type drain diffusion region (LVNA (P-type)) 310, a first conduction type body 312, a device isolation film 314, a first conduction type well 316, a second conduction type deep sink region (DEEPN+) 318, a gate pattern 320, a source 322 and a drain 324. The first conduction type is different than to the second conduction type wherein the first conduction type may be a P-type and the second conduction type may be an N-type.

The first conduction type epitaxial layer (P-EPI) 300 may be grown on and/or over a semiconductor substrate, and the first and second conduction type buried layers (PBL) 306 and (NBL) 302 may be formed in the first conduction type epitaxial layer (P-EPI) 300. The first conduction type buried layer (PBL) 306 may be formed in the first conduction type epitaxial layer (P-EPI) 300 on and/or over one region of the second conduction type buried layer (NBL) 302.

The second conduction type high-voltage well 304 may be formed in the first conduction type epitaxial layer (P-EPI) 300 on and/or over another region of the second conduction type buried layer (NBL) 302.

The first conduction type drain diffusion region (LVNA (P-type)) 310 and the second conduction type drain diffusion region (LVNA (N-type)) 308 may be formed on and/or over still another region of the second conduction type buried layer (NBL) 302. That is, the first conduction type drain diffusion region (LVNA (P-type)) 310 may be formed to be connected to another region of the second conduction type buried layer (NBL) 302, and the second conduction type drain diffusion region (LVNA (N-type)) 308 may be formed in the first conduction type drain diffusion region (LVNA (P-type)) 310 to be connected to the drain 324 of the LDMOS device.

The first conduction type body 312 may be formed in a part of the first conduction type epitaxial layer (P-EPI) 300, and have a surface which is in contact with one lateral surface of the second conduction type drain diffusion region (LVNA (N-type)) 308. At this time, the first conduction type body 312 may be in contact with both the second conduction type drain diffusion region (LVNA (N-type)) 308 and the first conduction type drain diffusion region (LVNA (P-type)) 310. The first conduction type body 312 may include the source 322 and a P+ region 323.

The first conduction type drain diffusion region (LVNA (P-type)) 310 and the second conduction type drain diffusion region (LVNA (N-type)) 308 may be formed by a drive-in process using a single ion implantation mask. In the drive-in process, an ion implantation mask may be formed to expose upper portions of the first conduction type epitaxial layer (P-EPI) 300 corresponding to the first conduction type drain diffusion region (LVNA (P-type)) 310 and the second conduction type drain diffusion region 314. Thereafter, a process for implanting first conduction type impurity ions is performed, and a process for implanting second conduction type impurity ions is then performed.

In the first conduction type drain diffusion region (LVNA (P-type)) 310 and the second conduction type drain diffusion region (LVNA (N-type)) 308, when the LDMOS device in accordance with embodiments is connected to a high or low-side device, a P-N junction may be formed and turned on, thereby preventing holes or electrons from being injected into the semiconductor substrate.

More specifically, when the LDMOS device is used for a high-side device, the P-N junction may be turned on between the first conduction type drain diffusion region (LVNA (P-type)) 310 and the second conduction type drain diffusion region (LVNA (N-type)) 308. Thus, electrons generated in the first conduction type drain diffusion region (LVNA (P-type)) 310 may move to the first conduction type buried layer (PBL) 306, and electrons generated in the second conduction type drain diffusion region (LVNA (N-type)) 308 may be combined with holes in the first conduction type epitaxial layer (P-EPI) 300 and holes of the first conduction type body 312. Accordingly, the holes are not injected into the semiconductor substrate.

On the other hand, when the LDMOS device is used for a low-side device, electrons generated in the first conduction type drain diffusion region (LVNA (P-type)) 310 may move to the second conduction type buried layer (NBL) 302, and electrons generated in the second conduction type drain diffusion region (LVNA (N-type)) 308 may be combined with holes in the first conduction type epitaxial layer (P-EPI) 300 and holes of the first conduction type body 312. Accordingly, the holes are not injected into the semiconductor substrate.

As described above, since the LDMOS device in accordance with embodiments further includes the first conduction type drain diffusion region (LVNA (P-type)) 310, it is possible to maximize the electric field reduction effect of the second conduction type drain diffusion region (LVNA (N-type)) 308, thereby minimizing on-resistance Rsp.

The first conduction type body 312 may include the source 322 and the P+ region 323 and be provided at one side of the gate pattern 320. The first conduction type well 316, second conduction type deep sink region (DEEPN+) 318, and a ground region (SPW) 326 may be provided on the other side of the gate pattern 320 in that order moving outwardly from the drain 324.

The first conduction type well 316 may include a dummy region 316a having a P+ region 316b. The dummy region 316a may be provided such that the LDMOS device produces a stable the voltage.

The second conduction type deep sink region (DEEPN+) 318 may be formed in the second conduction type high-voltage well 304, and may include a second conduction type well (NWELL) 318b connected to an N+ region 318a.

As described above, by providing the second conduction type deep sink region (DEEPN+) 318 including the second conduction type well (NWELL) 318b in the second conduction type high-voltage well 304 and the second conduction type buried layer (NBL) 302, it is possible to prevent holes or electrons generated due to voltage applied to the drain 324 from flowing into the semiconductor substrate.

In the LDMOS device in accordance with embodiments, a voltage V_{S/B} may be applied to the first conduction type body 312 and the source 322, and a voltage V_{DS} may be applied to the drain 324. Further, an isolation voltage V_{ISO} may be applied to the second conduction type deep sink region (DEEPN+) 318 including the second conduction type well (NWELL) 318b.

The LDMOS device in accordance with embodiments configured as described above may have the drain 324 to which a backward bias is applied, and can be used for a low-side device and a high-side device.

Example FIG. 4 is a cross sectional view illustrating an operation performed when the LDMOS device in accordance with embodiments is used for a high-side device.

As illustrated in example FIG. 4, when the LDMOS device is used for a high-side device, that is, when the voltage V_{DS} which is applied to the drain 324 is lower than the voltage V_{S/B} which is applied to the source 322 and the first conduction type body 312, a P-N junction may be forwarded (turned on) only within the LDMOS device, that is, within the semiconductor substrate. Hence, holes are not injected into the semiconductor substrate. More specifically, as the P-N junction between the second conduction type drain diffusion region (LVNA (N-type)) 308 and the first conduction type drain diffusion region (LVNA (P-type)) 310 is turned on, electrons in the first conduction type drain diffusion region 314 may move to the first conduction type buried layer (PBL) 306 and combine with the holes in the first conduction type body 312 and the first conduction type epitaxial layer (P-EPI) 300, thereby preventing the holes from being injected into the semiconductor substrate. It is possible, therefore, to isolate the LDMOS device from the semiconductor substrate.

Example FIG. 5 is a cross sectional view illustrating an operation performed when the LDMOS device in accordance with embodiments is used for a low-side device.

As illustrated in FIG. 5, when the 6LDMOS device is used for a low-side device, that is, when the voltage which is applied to the drain 324 is a negative bias, a P-N junction may be forwarded (turned on) only within the semiconductor substrate. Hence, holes are not implanted into the semiconductor substrate. More specifically, as the P-N junction between the second conduction type drain diffusion region (LVNA (N-type)) 308 and the first conduction type drain diffusion region (LVNA (P-type)) 310 is turned on, electrons generated in the second conduction type drain diffusion region (LVNA (N-type)) 308 may move to the first conduction type buried layer (PBL) 306 and combine with the holes in the first conduction type body 312 and the first conduction type epitaxial layer (P-EPI) 300, thereby preventing the electrons from being injected into the semiconductor substrate. It is possible, therefore, to isolate the LDMOS device from the semiconductor substrate and to use a LDMOS device having the same structure for a high-side device and a low-side device.

Further, the second conduction type high-voltage well 304 serving as a guard ring against electrons is formed only around the second conduction type deep sink region (DEEPN+) 318, thereby minimizing the size of the semiconductor chip.

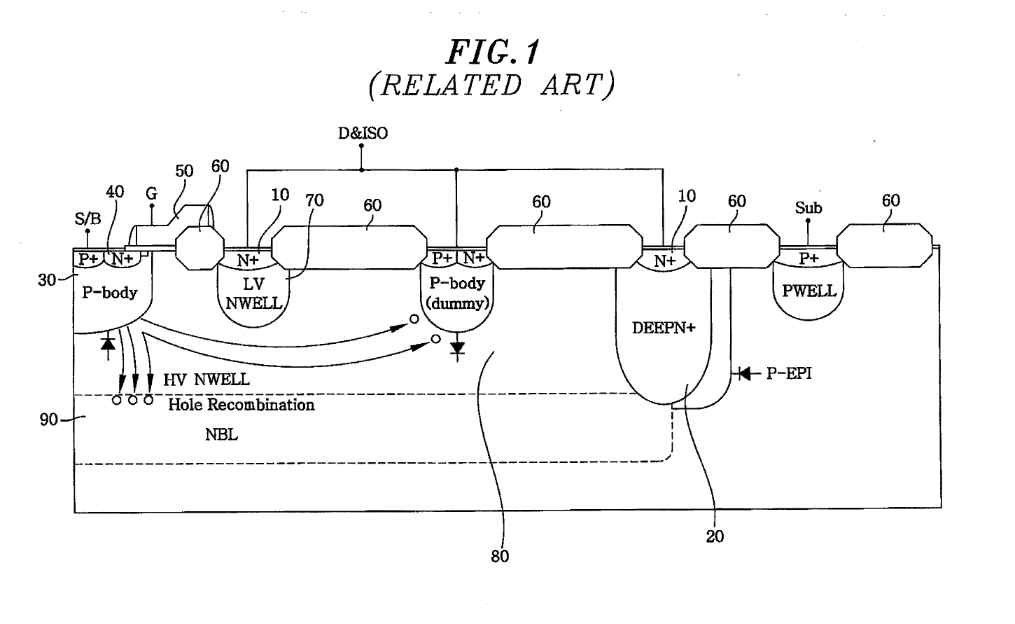

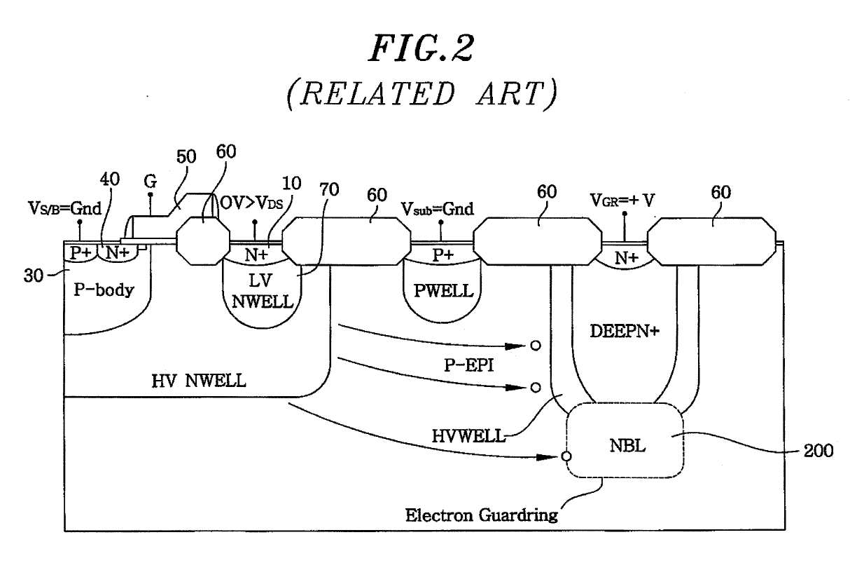

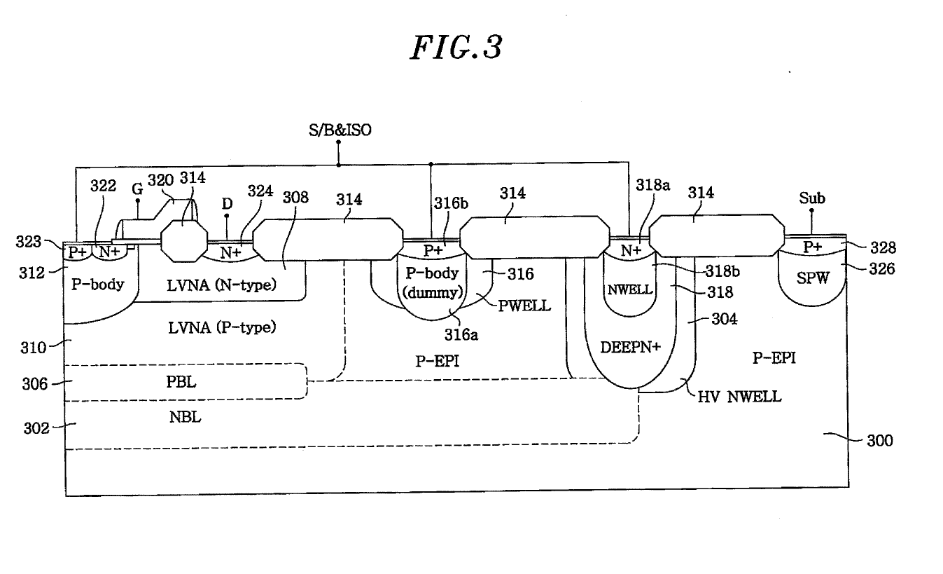

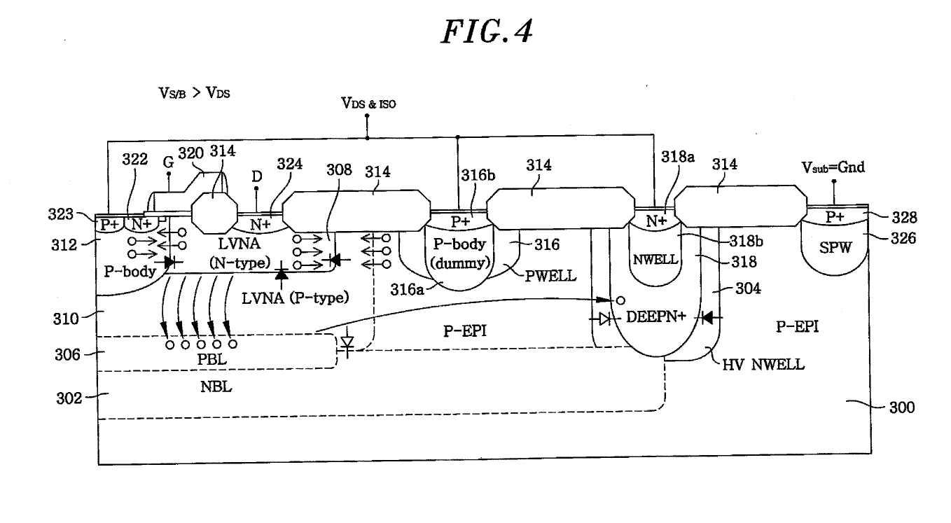

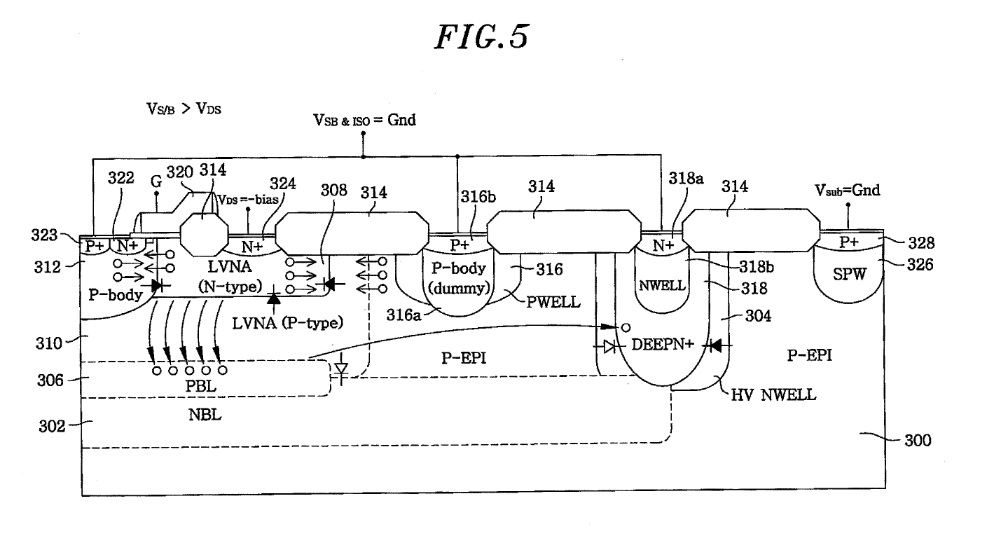

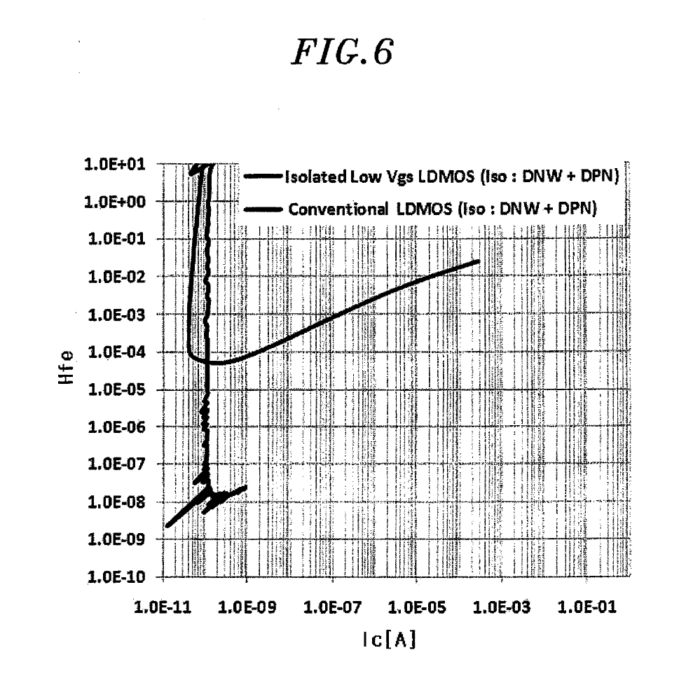

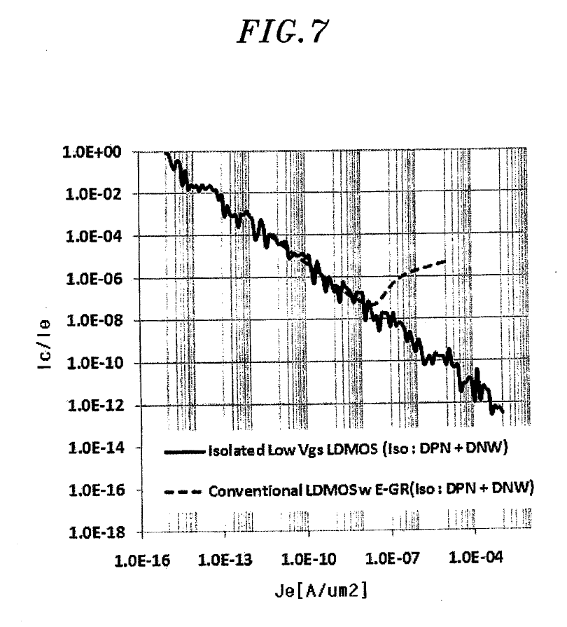

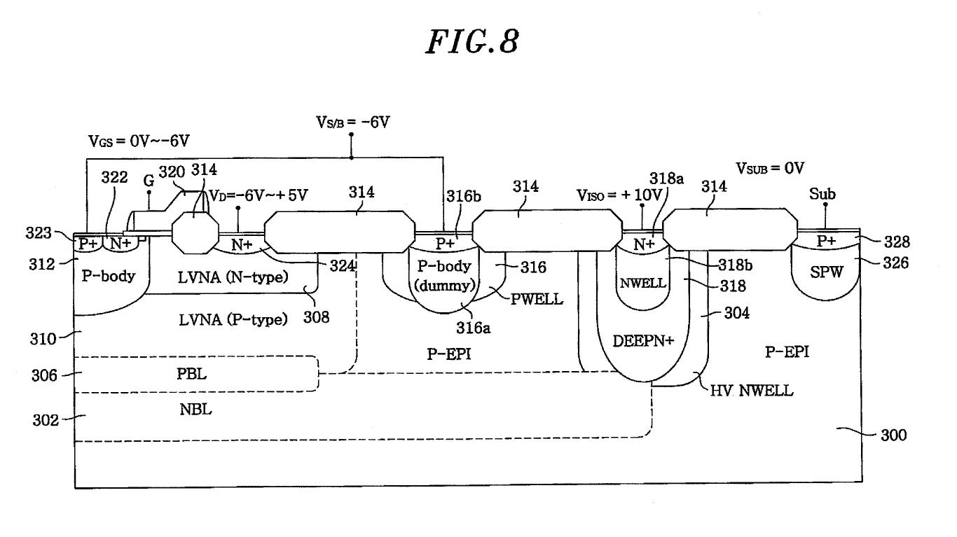

Example FIG. 6 illustrates the current gain Hfe of parasitic PNP measured in the LDMOS device in accordance with embodiments. That is, it can be understood that the current gain is smaller than that of the LDMOS device of the related art illustrated in FIG. 1 in which only a second conduction type deep sink region serves as a guard ring against holes. Further, it can be also understood that the LDMOS device may be completely isolated since the current gain Hfe of parasitic PNP is about 1E-8.

As illustrated in example FIG. 7, an alpha value Ic/Ie which is the ratio of a collector current Ic to an emitter current Ie when the LDMOS device has parasitic NPN. That is, as illustrated in example FIG. 7, since there is little collector current Ic even though the emitter current Ie increases, it can be understood that the LDMOS device may be completely isolated.

Example FIG. 8 illustrates a case where the LDMOS device is applied to an AMOLED.

As illustrated in example FIG. 8, when the LDMOS device is applied to an AMOLED, a negative bias is applied to the drain 324 of the LDMOS device, and a positive bias is applied to V_{ISO}. The LDMOS device in accordance with embodiments, therefore, can be applied to various circuits, such as an AMOLED or battery charging, in which a negative bias is applied to a drain.

Since the LDMOS device in accordance with embodiments has a P-type implanted region, it is possible to maximize the reduction effect of an electric field in an N-type implanted region, thereby minimizing resistance Rsp compared to the LDMOS device of the related art.

Although embodiments have been described, it should be understood that numerous other modifications and embodiments can be devised by those skilled in the art that fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the components parts and/or arrangements, alternative uses will also be apparent to those skilled in the art.

What is claimed is:

1. A lateral double diffused metal oxide semiconductor (LDMOS) device comprising:
an epitaxial layer having a first conduction type;
a first buried layer having a second conduction type formed in the epitaxial layer;
a first high-voltage well having the second conduction type formed above one region of the first buried layer;
a first drain diffusion region having the first conduction type formed above another region of the first buried layer;
a second drain diffusion region having the second conduction type formed in a partial region of the first drain diffusion region, the second drain diffusion region including a gate pattern and a drain region; and
a first body having the first conduction type including a source region and having a surface in contact with the second drain diffusion region.

2. The LDMOS device of claim 1, wherein the first high-voltage well comprises:
an N+ region;
a first well having the second conduction type; and
a deep sink region having the second conduction type.

3. The LDMOS device of claim 1, further comprising:
a second well having the first conduction type formed between the first high-voltage well and the first drain diffusion region.

4. The LDMOS device according to claim 3, wherein the second well comprises a P+ region and a dummy region into which first conduction type impurity ions are implanted.

5. The LDMOS device of claim 4, wherein the second well, the first drain diffusion region, and the first high-voltage well are isolated from each other by a device isolation film.

6. The LDMOS device of claim 1, wherein the first drain diffusion region and the second drain diffusion region are formed by a drive-in process.

7. The LDMOS device of claim 1, further comprising:
a second buried layer having the first conduction type formed between the first drain diffusion region and the first buried layer.

8. The LDMOS device of claim 1, wherein a P-N junction of the second drain diffusion region and the first drain diffusion region is activated based on a voltage applied to the drain region.

9. A lateral double diffused metal oxide semiconductor (LDMOS) device comprising:
an N-type buried layer having a first region and a second region;
an N-type high-voltage well formed above the first region of the N-type buried layer;
a P-type drain diffusion region formed above the second region of the N-type buried layer;
an N-type drain diffusion region formed above at least a portion of the P-type drain diffusion region; and
a P-type body having a source region and having a first surface contacting a first surface of the N-type drain diffusion region.

10. The LDMOS device of claim 9, wherein the N-type buried layer, the P-type buried layer, the N-type high-voltage well, and the P-type body are formed in a P-type epitaxial layer.

11. The LDMOS device of claim 9, wherein:
the P-type drain diffusion region has a first surface that contacts a first surface of the N-type buried layer; and
the P-type body has a second surface that contacts a second surface of the P-type drain diffusion region.

12. The LDMOS device of claim 9, further comprising:
a P-type well formed between the N-type high-voltage well and the P-type drain diffusion region.

13. The LDMOS device of claim 9, further comprising:
a P-type buried layer formed above a second region of the N-type buried layer,
wherein the P-type drain diffusion region is formed above at least a portion of the P-type buried layer.

14. The LDMOS device of claim 9, wherein a P-N junction of the N-type drain diffusion region and the P-type drain diffusion region is activated based on a voltage applied to a drain region of the LDMOS device.

15. A lateral double diffused metal oxide semiconductor (LDMOS) device comprising:
a P-type buried layer;
a P-type high-voltage well formed above a first region of the P-type buried layer;
an N-type drain diffusion region formed above a second region of the P-type buried layer;
a P-type drain diffusion region formed above at least a portion of the N-type drain diffusion region; and
an N-type body having a source region and having a first surface contacting a first surface of the P-type drain diffusion region.

16. The LDMOS device of claim 15, wherein the P-type buried layer, the N-type buried layer, the P-type high-voltage well, and the N-type body are formed in an N-type epitaxial layer.

17. The LDMOS device of claim 15, wherein:
the N-type drain diffusion region has a first surface that contacts a first surface of the P-type buried layer; and
the N-type body has a second surface that contacts a second surface of the N-type drain diffusion region.

18. The LDMOS device of claim 15, further comprising:
an N-type well formed between the P-type high-voltage well and the N-type drain diffusion region.

19. The LDMOS device of claim 15, further comprising:
an N-type buried layer formed above a second region of the P-type buried layer,
wherein the N-type drain diffusion region is formed above at least a portion of the N-type buried layer.

20. The LDMOS device of claim 15, wherein a P-N junction of the P-type drain diffusion region and the N-type drain diffusion region is activated based on a voltage applied to a drain region of the LDMOS device.
